(19) United States
(12) Patent Application Publication
(10) Pub. No.: US 2026/0299441 A1
(43) Pub. Date: Oct. 1, 2026

(54) PROTECTIVE DEVICE FOR A VACUUM SEAL

(71) Applicant: ASML Netherlands B.V., Veldhoven (NL)

(72) Inventors: Bradley Robert Adams, San Diego, CA (US); Muchen Xu, San Diego, CA (US); Daniel Steven, San Diego, CA (US); Arun Kumar Panneerselvam, San Diego, CA (US); Armin Bernhard Ridinger, San Diego, CA (US)

(21) Appl. No.: 19/475,996

(22) PCT Filed: Apr. 5, 2024
(86) PCT No.: PCT/EP2024/059409

§ 371 Date: Oct. 16, 2025

Related U.S. Application Data
(60) Provisional application No. 63/499,748, filed on May 3, 2023.

(51) Int. Cl. G03F 7/00

(52) U.S. Cl. CPC G03F 7/70841; G03F 7/7095

(57) ABSTRACT

An apparatus includes: a vacuum sealing device chemically reactive to a target material in an environment, the vacuum sealing device fixed between a first fitting and a second fitting; and a protective device chemically non-reactive to the target material, the protective device positioned between the environment and the vacuum sealing device. When the apparatus is in a first mode of operation, the protective device defines one or more test pathways between the environment and the vacuum sealing device, the one or more test pathways including one or more through pathways within the protective device. When the apparatus is in a second mode of operation, the protective device blocks passage of target material from the environment to the vacuum sealing device.

### CROSS REFERENCE TO RELATED APPLICATION

This application claims priority to U.S. Application No. 63/499,748, filed May 3, 2023, and which is incorporated herein in its entirety by reference.

### TECHNICAL FIELD

The disclosed subject matter relates to a protective device for a vacuum sealing device for a vacuum chamber of an extreme ultraviolet (EUV) light source.

### BACKGROUND

Extreme ultraviolet (EUV) light, for example, electromagnetic radiation having wavelengths of 100 nanometers (nm) or less (also sometimes referred to as soft x-rays), and including light at a wavelength of, for example, 20 nm or less, between 5 and 20 nm, or between 13 and 14 nm, can be used in photolithography processes to produce extremely small features in substrates, for example, silicon wafers, by initiating polymerization in a resist layer. Methods for generating EUV light include, but are not limited to, altering the physical state of a source material to a plasma state. The source material includes a compound or an element, for example, xenon, lithium, or tin, with an emission line in the EUV range. In one such method, often termed laser produced plasma (“LPP”), the required plasma is produced by irradiating a source material, for example, in the form of a droplet, stream, or cluster of source material, with an amplified light beam that can be referred to as a drive laser. For this process, the plasma is typically produced in a sealed vessel, for example, a vacuum chamber, and monitored using various types of metrology equipment. The source material, such as xenon, lithium, or tin, which emit in the EUV range when in the plasma state, are commonly referred to as target material since they are targeted and irradiated by the drive laser.

### SUMMARY

In some implementations, an apparatus includes: a vacuum sealing device chemically reactive to a target material in an environment, the vacuum sealing device fixed between a first fitting and a second fitting; and a protective device chemically non-reactive to the target material. The protective device is positioned between the environment and the vacuum sealing device. The protective device defines a test pathway between the environment and the vacuum sealing device when the environment is at a test temperature at which the target material is non-migrating, the test pathway including one or more through pathways within the protective device.

Implementations can include one or more of the following features. For example, the vacuum sealing device can include a soft metal or a polyimide-based plastic. The vacuum sealing device can include a coating over a bulk matter.

The vacuum sealing device and the protective device can each have a closed-path geometry and the protective device can be disposed inside the vacuum sealing device. The vacuum sealing device and the protective device can each have a toroidal geometry and the protective device can be disposed radially inside the vacuum sealing device. A cross-sectional geometry of the protective device taken along a radial direction can include a rectangular region. A cross-sectional geometry of the protective device taken along a radial direction can include at least one a triangular protrusion extending out from a central region. The cross-sectional geometry of the protective device taken along a radial direction can include two triangular protrusions, each triangular protrusion extending out from a distinct side of a central region.

The vacuum sealing device can be configured to compress upon joining the first fitting and the second fitting such that a vacuum seal is formed at the vacuum sealing device.

The protective device can include or be made of a polymer. The protective device can include or be made of an elastomer or a polyimide-based plastic. The protective device can be non-hermetically sealing.

The through pathways can include through holes that extend through the protective device. The through holes can include conduits that extend through the protective device along an angle that is offset from a radial direction or along a tortuous path through the protective device.

A cross-sectional area of the test pathway can be reduced or eliminated when the environment is at a temperature that is greater than or equal to a melting temperature of the target material. The reduced cross-sectional area can be small enough to block passage of the target material between the environment and the vacuum sealing device. A cross-section of the test pathway between the environment and the vacuum sealing device when the environment is at the test temperature can be large enough to permit passage of a test substance from the environment to the vacuum sealing device. The test substance can include or can be helium gas.

In other general aspects, an extreme ultraviolet (EUV) light source includes: a chamber defining an interior in which a target material is provided; at least one sealing apparatus in fluid communication with the interior and configured to seal a first fitting and a second fitting to thereby define an internal environment for target material. The sealing apparatus includes: a vacuum sealing device chemically reactive to the target material in the internal environment, the vacuum sealing device fixed between the first and second fittings; and a protective device chemically non-reactive to the target material, the protective device positioned between the internal environment and the sealing device. The protective device defines a test pathway between the internal environment and the vacuum sealing device when at a test temperature at which the target material is non-migrating, the test pathway including one or more through pathways within the protective device.

Implementations can include one or more of the following features. For example, the vacuum sealing device can include or be made of a soft metal. The protective device can include or be made of an elastomer or a polyimide-based plastic.

The vacuum sealing device and the protective device can each have a closed-path geometry and the protective device can be disposed radially inside the vacuum sealing device. A cross-sectional geometry of the protective device taken along a radial direction can include at least one a triangular protrusion extending out from a central region.

The vacuum sealing device can be configured to compress upon joining the first fitting and the second fitting such that a vacuum seal is formed at the vacuum sealing device.

The through pathways within the protective device can include through holes that extend through the protective device. The through holes can extend along a tortuous path through the protective device.

The sealing apparatus can be positioned in a target material generator or in a target material capture system. The target material can include tin or a tin alloy.

The EUV light source can include a clamp adapted to cause the first fitting and the second fitting to become pressed together to form the vacuum seal at the vacuum sealing device between the first fitting and the second fitting.

The sealing apparatus can be positioned between the chamber interior and a target material capture device. A cross-sectional area of the test pathway can be reduced when the internal environment is at a temperature that is greater than or equal to a melting temperature of the target material, and the reduced cross-sectional area can be small enough to block passage of the target material between the internal environment and the vacuum sealing device. And, a cross-section of the test pathway between the internal environment and the vacuum sealing device when the environment is at a test temperature below the melting temperature of the target material can be large enough to permit passage of a test substance from the internal environment to the vacuum sealing device.

In other general aspects, an apparatus includes: a vacuum sealing device chemically reactive to a target material in an environment, the vacuum sealing device fixed between a first fitting and a second fitting; and a protective device chemically non-reactive to the target material, the protective device positioned between the environment and the vacuum sealing device. When the apparatus is in a first mode of operation, the protective device defines one or more test pathways between the environment and the vacuum sealing device, the test pathways including one or more through pathways within the protective device, and when the apparatus is in a second mode of operation, the protective device blocks passage of target material from the environment to the vacuum sealing device.

Implementations can include one or more of the following features. For example, in the second mode of operation, the one or more test pathways can have a reduced cross-sectional area that is small enough to block passage of the target material from the environment to the vacuum sealing device.

In other general aspects, a method includes: operating an apparatus in a first mode of operation in which a protective device adjacent an environment defines one or more test pathways between the environment and a vacuum sealing device and through the protective device, the vacuum sealing device positioned between a first fitting and a second fitting that define the environment; and operating the apparatus in a second mode of operation in which the protective device blocks passage of target material from the environment to the vacuum sealing device.

The details of one or more implementations are set forth in the accompanying drawings and the description below. Other features will be apparent from the description and drawings, and from the claims.

### DESCRIPTION OF DRAWINGS

The accompanying drawings, which are incorporated herein and form part of the specification, illustrate the present disclosure and, together with the description, further serve to explain the principles of the present disclosure and to enable a person skilled in the relevant art(s) to make and use implementations described herein.

FIG. 1A is a side cross-sectional view of an implementation of a coupling assembly including a sealing apparatus between a first fitting and a second fitting, the sealing apparatus including a vacuum sealing device and a protective device between an environment inside the coupling assembly and the vacuum sealing device, and the sealing apparatus is in a first mode of operation;

FIG. 1B is a top cross-sectional view taken along the 1B-1B plane of the coupling assembly of FIG. 1A;

FIG. 1C is a close-up side cross-sectional view showing detail of the sealing apparatus of FIG. 1A while in a first mode of operation;

FIG. 2A is a side cross-sectional view of the coupling assembly of FIG. 1A, and the sealing apparatus is in a second mode of operation;

FIG. 2B is a top cross-sectional view taken along the 2B-2B plane of the coupling assembly of FIG. 2A;

FIG. 2C is a close-up side cross-sectional view showing detail of the sealing apparatus of FIG. 1A while in a second mode of operation;

FIG. 3 is a top cross-sectional view taken along the 1B-1B plane of another implementation of the coupling assembly of FIG. 1A;

FIG. 4 is a top cross-sectional view taken along the 1B-1B plane of another implementation of the coupling assembly of FIG. 1A;

FIG. 5 is a perspective view of an implementation of a protective device that can be used in the sealing apparatus of FIGS. 1A-2C;

FIGS. 6A-6C are cross-sectional views of respective implementations of the protective device of FIG. 5 taken along a radial axial plane;

FIGS. 7A-7C are cross-sectional views of respective implementations of the protective device of FIG. 5 taken along a radial transverse plane;

FIG. 8A is a close-up perspective view of another implementation of a protective device that can be used in the sealing apparatus of FIGS. 1A-2C;

FIG. 8B is a close-up cross-sectional perspective view along a radial axial plane of an implementation of the protective device of FIG. 8A;

FIG. 8C is a close-up cross-sectional perspective view along a radial axial plane of an implementation of the protective device of FIG. 8A;

FIG. 9 is a block diagram of an implementation of an extreme ultraviolet (EUV) light source in which the sealing apparatus of FIGS. 1A-8C can be used;

FIG. 10 is a block diagram of an implementation of a target material capture apparatus in the EUV light source of FIG. 9 and including at least one sealing apparatus of FIGS. 1A-8C; and

FIG. 11 is a side cross-sectional view of an implementation of a sealing apparatus in the target material capture apparatus of FIG. 10.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DESCRIPTION

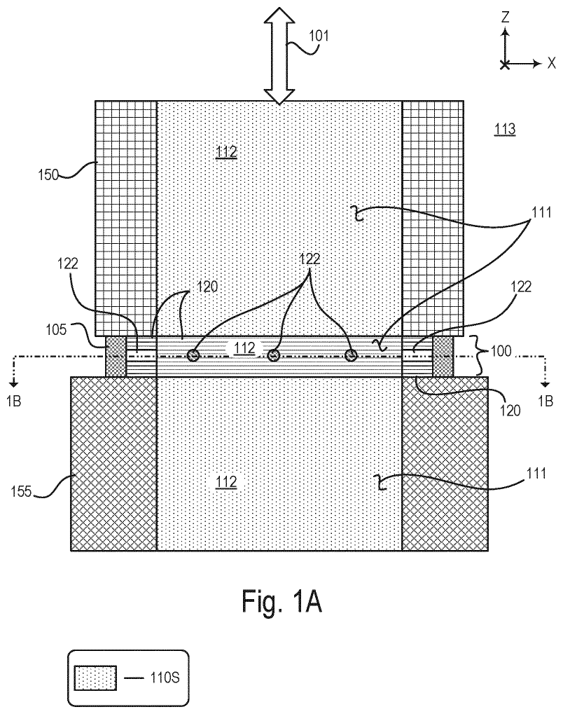

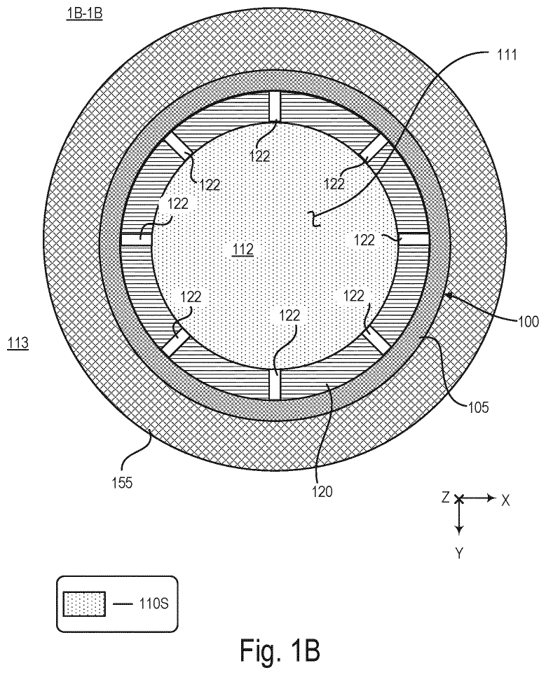

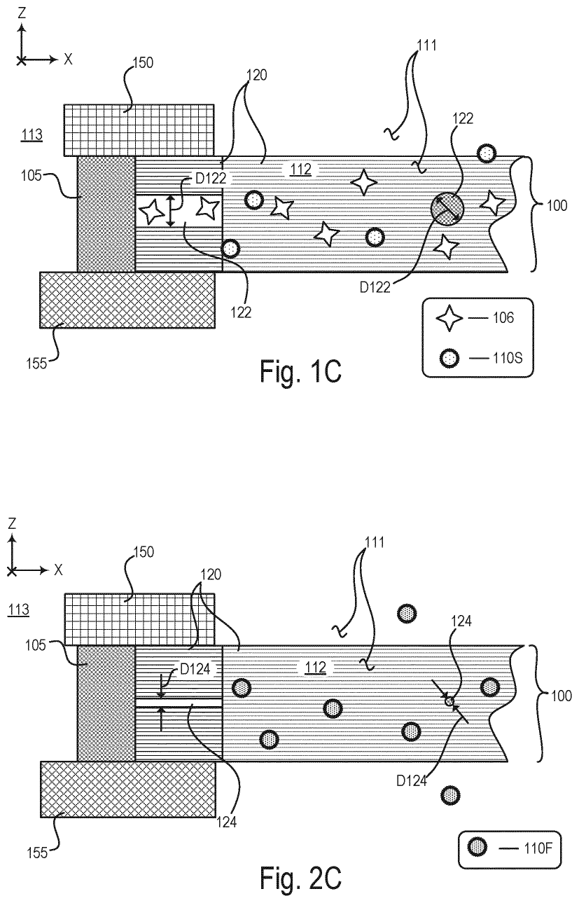

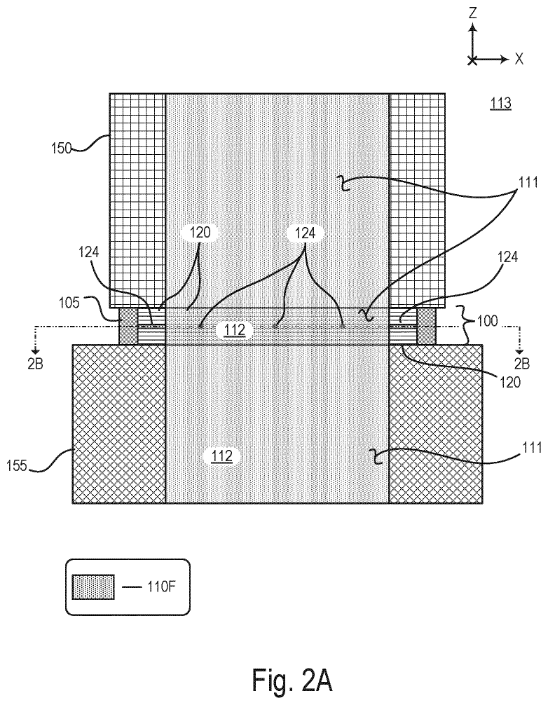

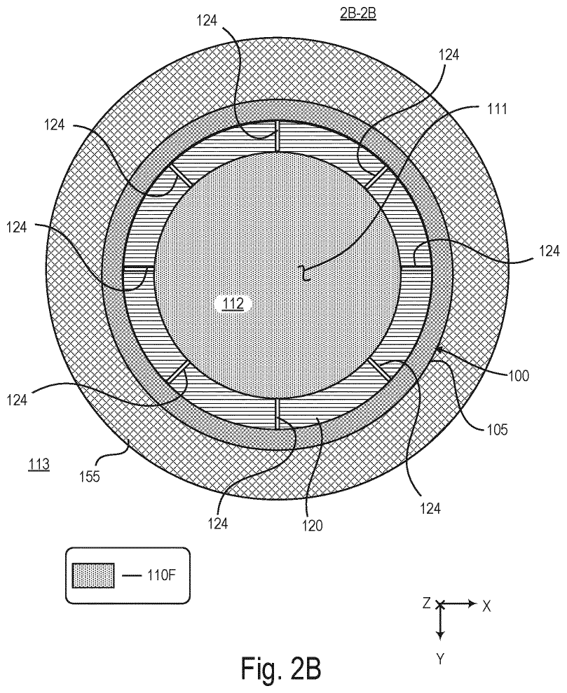

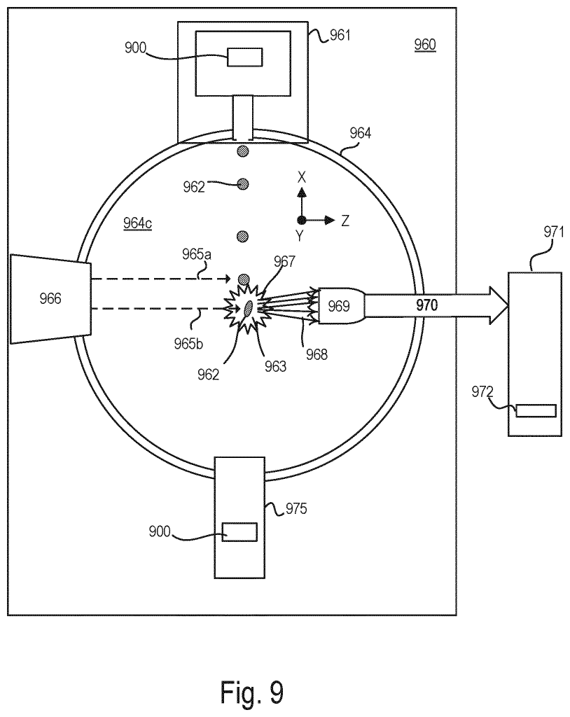

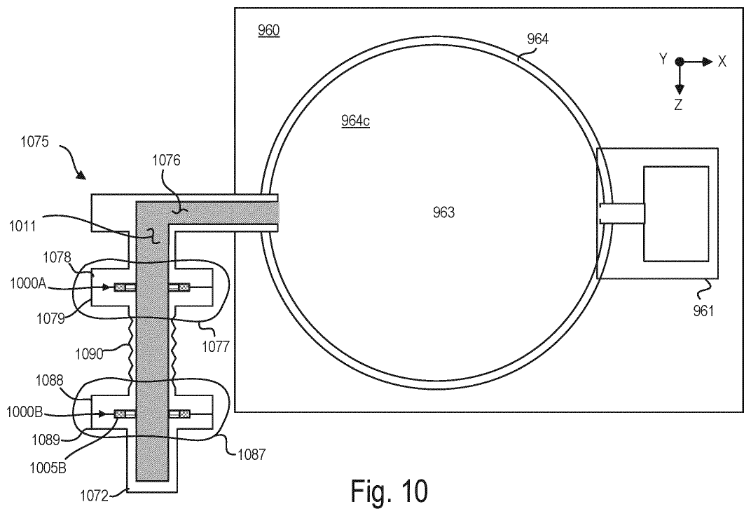

Referring to FIGS. 1A-1C and 2A-2C, an apparatus (or coupling assembly) 100 includes a vacuum sealing device 105 and a protective device 120. The vacuum sealing device 105 is fixed between a first fitting 150 and a second fitting 155. An environment 111 is defined within an open passage 112 that is defined within the first fitting 150, the second fitting 155, and the apparatus 100. The open passage 112 has an extent in all directions (X, Y, Z), and a fluid flow path 101 for target material 110S, 110F generally follows along the Z axis (either along +Z or −Z directions) within the open passage 112. FIGS. 1A-1C show the apparatus 100 when operating in a first mode in which a first set of conditions exist for the environment 111 and FIGS. 2A-2C show the apparatus while operating in a second mode in which a second set of conditions exist for the environment 111. The open passage 112 can be in fluid communication with an interior of a vacuum chamber (such as shown in FIGS. 9 and 10).

In the first mode of operation (FIGS. 1A-1C), the environment 111 is held at a test temperature at which the target material 110S is non-migrating, which means that the target material 110S is not able to migrate to the vacuum sealing device 105. For example, the test temperature of the environment 111 can be below or significantly below a melting point or temperature of the target material 110S. If the target material 110S includes tin, then the test temperature can be below the melting point of tin. In this first mode of operation, the target material 110S can be, for example, in a solid state. The melting point of tin is about 232° C. Thus, in some implementations, the test temperature is below 200° C. In other implementations, the test temperature is below 100° C., or even in the range of 10° C. to 30° C., or about 20° C. The test temperature is the temperature at which the vacuum sealing device 105 is installed, and the sealing capacity of the vacuum sealing device 105 is verified at the test temperature. At the test temperature (in the first mode of operation), the protective device 120 provides one or more test pathways 122 (which can be considered gas pathways). For verification, as discussed below in more detail, at least one test pathway 122 for a test gas (such as, for example, helium) is present in the protective device 120 between the vacuum sealing device 105 and the open passage 112 in the first mode of operation. A detector within the vacuum chamber can be configured to detect the externally applied test gas to determine whether the vacuum sealing device 105 is correctly installed.

In the second mode of operation (FIGS. 2A-2C), the environment 111 is held at an operational temperature at which the target material 110F is migrating, which means that the target material 110F would be able to migrate to the vacuum sealing device 105 if there were no obstruction between the environment 111 and the vacuum sealing device 105. The operational temperature of the environment 111 is greater than the test temperature of the environment 111. Thus, the operational temperature of the environment 111 can be greater than the melting point or temperature of the target material 110F. In this first mode of operation, the target material 110F can be, for example, in a liquid or gaseous state. For example, if the target material 110F includes tin, then the operational temperature can be above the melting point of tin. In some implementations, the operational temperature is greater than 250° C. or is in a range from 275° C. to 325° C., or is about 300° C.

The vacuum sealing device 105 is made of a material and geometry that is designed to perform a vacuum sealing function. Specifically, the vacuum sealing device 105 is made of a material and geometry that holds a vacuum seal through multiple cycles between the first mode of operation (FIGS. 1A-1C) and the second mode of operation (FIGS. 2A-2C). For example, the vacuum sealing device 105 is made in a manner that enables cycling between the first mode of operation (FIGS. 1A-1C) and the second mode of operation (FIGS. 2A-2C) for at least one year of operation. For example, the vacuum sealing device 105 can maintain its vacuum sealing function even when performing through tens of cycles hundreds of cycles, thousands of cycles, or more and until the first fitting 150 and the second fitting 155 need to be separated for service. The vacuum seal is a hermetic seal that is able to withstand a pressure differential. For example, the vacuum sealing device 105 can be configured to maintain a hermetic seal up to pressures greater than 10 pounds per square inch (PSI), greater than 100 PSI, greater than 1000 PSI, greater than 10,000 PSI, greater than 20,000 PSI, or greater than 30,000 PSI.

The material of the vacuum sealing device 105 is selected to perform the vacuum sealing function and to perform it well through many cycles between the first mode of operation (FIGS. 1A-1C) and the second mode of operation (FIGS. 2A-2C). Unfortunately, the most suitable materials for performing this vacuum sealing function also tend to be chemically reactive with the target material 110S, 110F within the environment 111. Thus, the vacuum sealing device 105 may be chemically reactive to the target material 110S, 110F within the environment 111. On the other hand, the protective device 120 is made of a material that is chemically non-reactive to the target material 110S, 110F within the environment 111. Because of this, the protective device 120 is positioned between the environment 111 and the vacuum sealing device 105 in a manner that enables the protective device 120 to block passage of target material 110F from traveling from the environment 111 to the vacuum sealing device 105 when operating in the second mode of operation (FIGS. 2A-2C). In this way, the positioning and geometry of the protective device 120 reduce or prevent interaction between the target material 110S or 110F and the vacuum sealing device 105. Additionally, the protective device 120 defines at least one test pathway 122 between the environment 111 and the vacuum sealing device 105 when the apparatus 100 is operating in the first mode of operation (FIGS. 1A-1C). In the example of FIGS. 1A and 1B, eight test pathways 122 are shown, but there can be fewer than eight or more than eight test pathways 122 and the test pathways 122 may be located in various orientations. Moreover, the material of the protective device 120 thermally expands more than the material of the vacuum sealing device 105 and the first and second fitting 150, 155 as the apparatus 100 transitions from the first mode of operation (at the test temperature) to the second mode of operation (at the operational temperature). This enables the protective device 120 to protect the vacuum sealing device 105 against target material 110F while still providing the one or more test pathways 122 in the first mode of operation.

As discussed above, in the first mode of operation (FIGS. 1A-1C), the environment 111 is held at the test temperature at which the target material 110S is non-migrating, while in the second mode of operation (FIGS. 2A-2C), the environment 111 is held at the operational temperature at which the target material 110F is migrating. The protective device 120 defines the at least one test pathway 122 while in the first mode of operation, as shown in FIGS. 1A-1C. However, as shown in FIGS. 2A-2C, in the second mode of operation, each of the one or more test pathways 122 has a significantly reduced cross-sectional area (taken along the direction along which fluid generally flows from the environment 111 to the vacuum sealing device 105). As the environment 111 heats up to reach the second mode of operation, the target material 110S becomes migrating (and converts to the target material 110F), but the protective device 120 is heating up at the same time and the heat causes the material of the protective device 120 to expand, which reduces the cross-sectional area of each test pathway 122. Moreover, this effect is even more pronounced because in the first mode of operation (FIGS. 1A-1C), the test pathways 122 are enclosed (other than at the side facing the environment 111 and the side facing the vacuum sealing device 105) within the body or bulk material of the protective device 120. Thus, effectively, each test pathway 122 is squeezed from all sides as the protective device 120 is heated as it transitions from the first mode of operation (FIGS. 1A-1C) to the second mode of operation (FIGS. 2A-2C). Each test pathway 122 that is present in the first mode of operation (FIGS. 1A-1C) transitions or changes to a target blocking region 124 in the second mode of operation (FIGS. 2A-2C). Each target blocking region 124 has such a small cross-sectional area that it blocks the size of the particles of the target material 110F.

Reference is specifically made to FIGS. 1C and 2C next because these drawings each show a close-up view of the protective device 120 while in the first mode of operation (FIG. 1C) and while in the second mode of operation (FIG. 2C).

In the first mode of operation (FIG. 1C), the test pathways 122 are fully open to permit a test substance 106 to pass between the environment 111 and an exterior 113 by way of the vacuum sealing device 105 if the vacuum sealing device 105 is not operating properly. The test pathways 122 provide a path for venting and to perform a leak check to ensure that the vacuum sealing device 105 is holding a vacuum seal at the interface between the first fitting 150 and the second fitting 155. Specifically, the test substance 106 (which can be air or a tracer gas such as helium) is able to pass from the exterior 113 and into the environment 111 through the test pathway 122 if the vacuum sealing device 105 fails to perform the sealing function. On the other hand, the test substance 106 would be blocked form passing from the exterior 113 and into the environment 111 through the test pathway 122 if the vacuum sealing device 105 has created a proper seal between the first and second fittings 150, 155. In the first mode of operation, the size or overall extent of each of the particles of the test substance 106 is smaller than a cross-sectional extent D122 of each test pathway 122. In some implementations, the test substance 106 is a gas such as helium. In such implementations, the cross-sectional extent D122 can be at least 10 micrometers (μm), at least 20 μm, at least 30 μm, at least 40 μm, or at least 50 μm to permit the passage of the helium as the test substance 106. Moreover, the largest size permitted for the cross-sectional extent D122 is governed by the ability of the protective device 120 to adequately transition to the second mode of operation (FIG. 2C). Note that in the first mode of operation (FIG. 1C), the temperature of the environment 111 is low enough that any target material 110S present in the environment 111 is non-migrating. Thus, if it is present in the environment 111, target material 110S would not have momentum and therefore would not move toward the test pathway 122 or pass through the test pathway 122 and access the vacuum sealing device 105. Because the target material 110S is non-migrating, while it is shown in FIG. 1C, it is not moving or moving very little.

In the second mode of operation (FIG. 2C), because the temperature of the environment 111 has been increased, the test pathways 122 within the protective device 120 have been shrunk because the temperature of the environment 111 is increased. In this way, each test pathway 122 that would be present in the first mode of operation has transitioned or changed to a target blocking region 124 in the protective device 120. The target blocking region 124 has a cross-sectional extent D124 that is much smaller than or even practically non-existent or zero when compared with the cross-sectional extent D122 of the test pathway 122. In particular, the cross-sectional extent D124 is so small that particles of the target material 110F are unable to pass through target blocking region 124. For example, the cross-sectional extent D124 can be less than a size or overall extent of each particle of the target material 110F. In this way, any particles of target material 110F in the environment 111 while operating in the second mode are prevented from reaching the vacuum sealing device 105.

The apparatus 100 is therefore designed with an architecture that divides functions between the vacuum sealing device 105 and the protective device 120. The vacuum sealing device 105 provides the first function of sealing, that is, to maintain a pressure differential between the environment 111 and an exterior 113 by forming a seal between the first fitting 150 and the second fitting 155. The vacuum sealing device 105 is configured to prevent or reduce leaks between the environment 111 and the exterior 113, that is, to keep the migrating target material 110F within the environment 111 and to prevent materials from the exterior 113 to enter the environment 111. Because the primary function of the vacuum sealing device 105 is to form and hold the vacuum seal, the material of the vacuum sealing device 105 is selected with this function in mind. However, materials that function to form and hold the vacuum seal may not be suitable for exposure to the target material 110S, 110F such that upon exposure to the target material 110S or 110F, such materials can be corroded or suffer compression set through multiple cycles between the first mode of operation and the second mode of operation.

Because of this, the protective device 120 provides the second function of protecting the vacuum sealing device 105 from the target material 110F. The protective device 120 is configured to block the target material 110F from reaching the vacuum sealing device 105. By preventing the target material 110F from reaching the vacuum sealing device 105, the protective device 120 increases the life of the vacuum sealing device 105. The protective device 120 also changes its functionality between the first mode of operation (FIGS. 1A-1C) and the second mode of operation (FIGS. 2A-2C). Thus, the protective device 120 permits the test substance 106 (such as the gas) to pass through the test pathway 122 while in the first mode of operation, but the protective device 120 provides a level of sealing (which is referred to as protection) against the passage of the particles of the target material 110F while in the second mode of operation. Thus, in implementations, the protective device 120 is not able to hold a hermetic seal.

Upon application of pressure against the first fitting 150 and the second fitting 155, the vacuum sealing device 105 is compressed (such as squeezed along the Z axis) and is deformed, thereby forming the seal. Accordingly, the vacuum sealing device 105 can be made of a bulk matter such as a soft metal. Examples of suitable soft metals include gold, silver, indium, tin, zinc, aluminum, thorium, copper, nickel, soft iron, stainless steel, titanium, tantalum, brass, and bronze. For example, in one implementation, the vacuum sealing device 105 is made of copper. Additionally, in some implementations, the vacuum sealing device 105 includes a coating over the bulk matter. Such coating can enhance the ability to seal at the interface between the first fitting 150 and the second fitting 155. For example, a coating on the bulk matter of the vacuum sealing device 105 can compensate for local defects and irregularities on the surfaces of the first fitting 150 and the second fitting 155 that come in contact with the vacuum sealing device 105. Additionally, a coating can protecting the bulk matter of the vacuum sealing device 105 against oxidation and corrosion and to protect the bulk matter from the environment 111. In some implementations, the coating can be silver or gold. In other implementations, the vacuum sealing device 105 is made of a polyimide-based plastic, an elastomer, or a heat resistant plastic.

The protective device 120 can be made of a polymer. In some implementations, the protective device 120 is made of an elastomer or a polyimide-based plastic. In some implementations, the protective device 120 is made of a perfluoroelastomer such as fluorinated, carbon-based synthetic rubber, fluorine kautschuk materials, (FKM or FFKM), neoprene, or nitrile rubber elastomer.

Polyimide-based plastics and elastomers are resistant to tin and can be suitable for this purpose, that is, for use in the protective device 120. Polyimide-based plastics are suitable for higher temperatures, including operational temperatures that exceed 300° C., tend to be harder than elastomers, and are thus easier to machine than elastomers. therefore, it can be easier to machine the test pathways 122 in the protective device 120 made of polyimide-based plastics than it would for one made of an elastomer. Polyimide-based plastics are less susceptible than elastomers to plastic deformation and thus they can be more robust with respect to thermal cycling between the first and second modes of operation, and also because the polyimide-based plastic is more stable at higher temperatures and outgasses less at higher temperatures than an elastomer.

On the other hand, elastomers can be preferred over polyimide-based plastics in certain applications because elastomers have a higher thermal expansion coefficient, and this enhances the ability to close the test pathways 122 at the operating temperature when transitioning to the second mode of operation. Elastomers can be softer and require less clamping force.

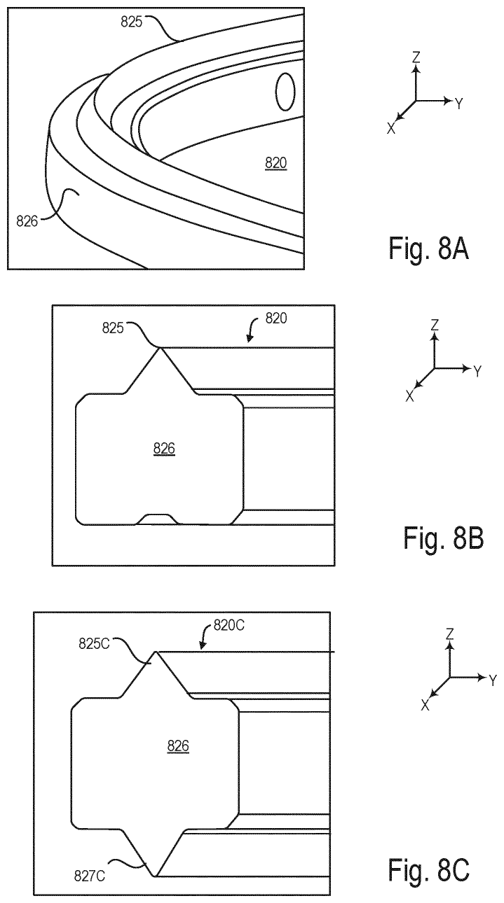

If it is desired to make the protective device 120 out of a polyimide-based plastic, then it may be useful or necessary to manufacture narrower test pathways 122 into the protective device; in this way, the narrower test pathways 122 would not need to close as much as they transition from the first mode of operation to the second mode of operation. Because polyimide-based plastics have improved elasticity, the protective device 120 made with a polyimide-based plastic can maintain the test pathways 122 in a reliable way when cycling between the first and second modes of operation, offering the ability to verify sealing capacity of the vacuum sealing device 105 over many cycles. Examples of protective devices 120 made with a polyimide-based plastic are shown in and discussed with respect to FIGS. 8A-8C.

In some implementations, the first fitting 150 and the second fitting 155 are made of stainless steel. Additionally, the first fitting 150 and the second fitting 155 can be coated with a material that is resistant to the target material 110S, 110F. For example, the first fitting 150 and the second fitting 155 can be coated with titanium nitride.

The geometry of the vacuum sealing device 105 is selected based on the geometry of the first fitting 150 and the second fitting 155 at their interface in the XY plane to ensure that the vacuum sealing device 105 performs the function of a vacuum seal. As shown in FIGS. 1B and 2B, the vacuum sealing device 105 and the protective device 120 have a closed-path geometry (in the XY plane). The closed-path geometry means that the vacuum sealing device 105 extends generally in the XY plane in a manner that it closes back on itself to form a closed path and the protective device 120 extends generally in the XY plane in a manner that it closes back on itself to form a closed path. The closed-path geometry of the vacuum sealing device 105 is needed to ensure that the vacuum seal extends all the way around the interface where the first fitting 150 and the second fitting 155 meet and where the vacuum sealing device 105 is positioned. The closed-path geometry of the protective device 120 is need to ensure that the protective device 120 prevents target material 110F from reaching the vacuum sealing device 105. The protective device 120 is disposed or positioned inside the vacuum sealing device 105 and closer to the environment 111.

In the example of FIGS. 1B and 2B, because the interface between the first fitting 150 and the second fitting 155 is annular, both the vacuum sealing device 105 and the protective device 120 are annular or toroidal in shape. This means that the vacuum sealing device 105 forms a ring in the XY plane and the protective device 120 forms a ring in the XY plane that is disposed radially inside the vacuum sealing device 105 in the XY plane.

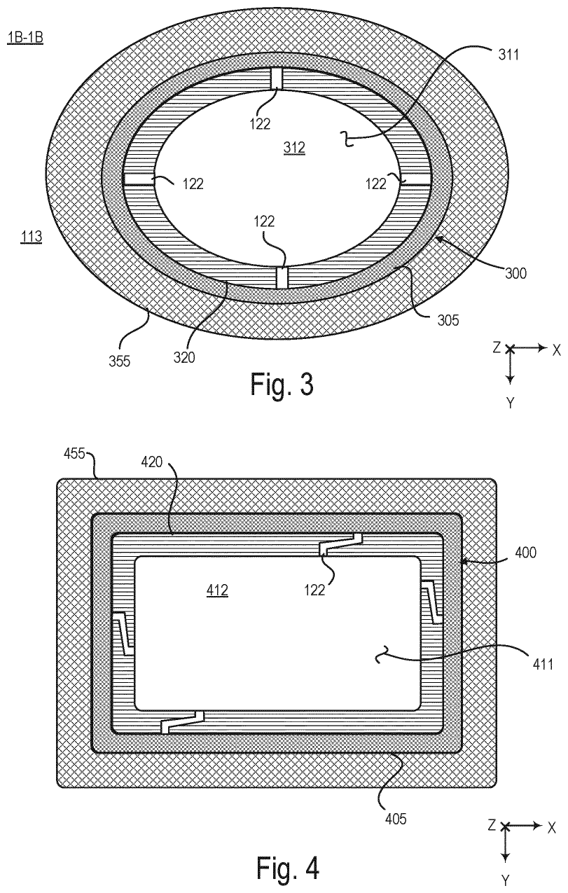

Other closed-path geometries (in the XY plane) are possible and depend on the shape of the interface between the first fitting 150 and the second fitting 155. For example, as shown in FIG. 3 (which is a cross-sectional view taken along the 1B-1B plane (which is in the XY plane) while operating in the first mode), the interface between the first fitting 150 (not shown in FIG. 3) and the second fitting 355 is oval, and apparatus 300 has an oval shape, which means that the vacuum sealing device 305 and the protective device 320 each have an oval shape. Moreover, the cross-sectional shape of the environment 311 taken in the XY plane is also oval, as is the cross-sectional shape of the open passage 312 that defines the environment 311. As another example, as shown in FIG. 4 (which is a cross-sectional view taken along the 1B-1B plane (which is in the XY plane) while operating in the first mode), the interface between the first fitting 150 (not shown in FIG. 4) and the second fitting 455 is rectangular, and therefore, the apparatus 400 has a rectangular shape, which means that the vacuum sealing device 405 and the protective device 420 each have a rectangular shape. Moreover, the cross-sectional shape of the environment 411 taken in the XY plane is also rectangular, as is the cross-sectional shape of the open passage 412 that defines the environment 411. As another example, while not shown, the cross-sectional shape of the interface and thus the apparatus 100 can take the form of a polygon in the XY plane or a more irregular closed-path shape.

Each pathway can have any suitable cross-sectional shape. In the example of FIGS. 1A-1C, each test pathway 122 has a circular cross-section. Other cross-sectional shapes that may be used include polygonal (such as rectangular or hexagonal), elliptical, and non-circular.

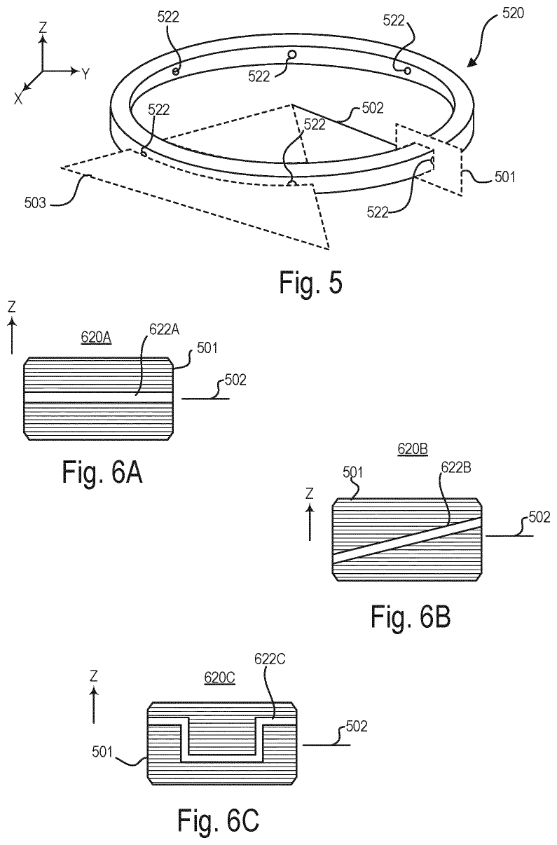

Referring to FIG. 5, an implementation 520 of the protective device 120 is shown in perspective view. In this implementation 520, the protective device 120 is toroidal or annular and includes six test pathways 522 around its circumference.

The cross-sectional geometry or shape of the protective device 520 taken along a plane 501 that is parallel with a radial direction 502 is generally rectangular. Implementations 620A, 620B, 620C of the cross-sectional view of the protective device 520 in the plane 501 are shown in FIGS. 6A, 6B, and 6C. As seen more clearly in these views, the rectangular body of the protective device 620A, 620B, 620C is chamfered. Moreover, the shape of the test pathways 622A, 622B, 622C are distinct in each of these implementations. In the protective device 620A of FIG. 6A, the test pathway 622A extends generally along the radial direction 502 through the bulk of the protective device 620A. In the protective device 620B of FIG. 6B, the test pathway 622B extends along a straight path that is skewed or angled relative to the radial direction 502 through the bulk of the protective device 620B. In the protective device 620C of FIG. 6C, the test pathway 622C extends along a step-wise path through the bulk of the protective device 620C. The test pathways 622B and 622C are therefore longer than the test pathway 622A, which means that the length of travel for particles of target material 110F to travel through the protective devices 620B, 620C, respectively, is greater than the length of travel for particles of target material 110F to travel through the protective device 620A. While not required, this extended length of travel for the test pathways 622B and 622C makes it harder for particles of target material 110F that might accidentally or unintentionally still be migrating while in the second mode of operation to reach the vacuum sealing device 105. The test pathway 622C can be a tortuous pathway, one that is marked by repeated twists, bends, or turns as it extends through the bulk of the protective device 620C.

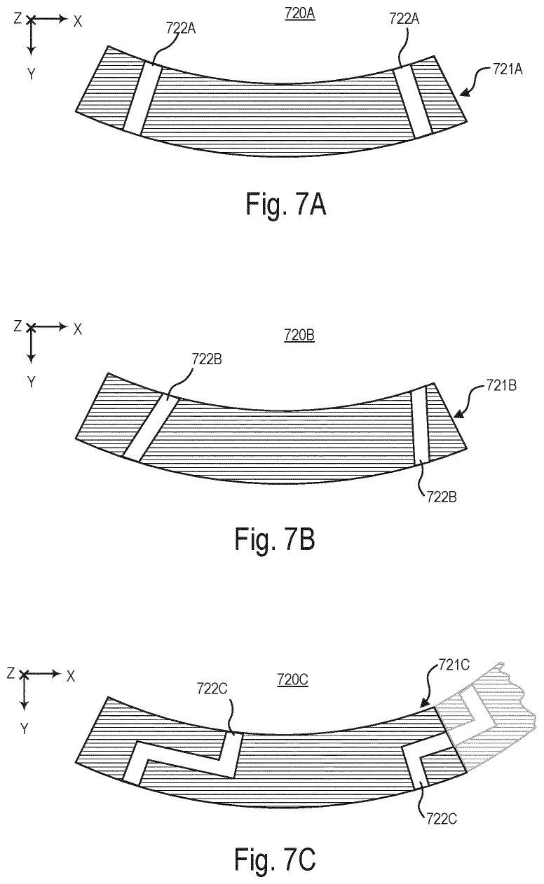

Referring again to FIG. 5, the cross-sectional geometry or shape of the protective device 520 taken along the XY plane is generally annular or toroidal. A planar cross-section 503 is sliced through the protective device 520 to show possible (but not limiting) shapes of the test pathways 522 in the XY plane. Annular sections 721A, 721B, 721C that are obtained from the planar cross-section 503 through the protective device 520 are shown in FIGS. 7A, 7B, and 7C, respectively. In the annular section 721A of protective device 720A (FIG. 7A), the test pathways 722A extend straight radially and through the bulk of the protective device 720A in the XY plane. Moreover, in the Z direction, the test pathways 722A can extend along the radial direction 502 (such as shown in FIG. 6A), at an angle relative to the radial direction (such as shown in FIG. 6B), or even in a step-wise fashion along the radial direction 502 (such as shown in FIG. 6C). In the annular section 721B of protective device 720B (FIG. 7B), the test pathways 722B extend at an angle radially and through the bulk of the protective device 720B in the XY plane. Moreover, in the Z direction, the test pathways 722B can extend along the radial direction 502 (such as shown in FIG. 6A), at an angle relative to the radial direction (such as shown in FIG. 6B), or even in a step-wise fashion along the radial direction 502 (such as shown in FIG. 6C). In the annular section 721C of protective device 720C (FIG. 7C), the test pathways 722C extend in a step wise fashion and through the bulk of the protective device 720C in the XY plane. A view of the protective device 720C is shown beyond the annular section 721C (in shadow) to show the complete test pathway 722C. Moreover, in the Z direction, the test pathways 722C can extend along the radial direction 502 (such as shown in FIG. 6A), at an angle relative to the radial direction (such as shown in FIG. 6B), or even in a step-wise fashion along the radial direction 502 (such as shown in FIG. 6C). The test pathways 722B and 722C are therefore longer than the test pathway 722A, which means that the length of travel for particles of target material 110F to travel through the protective devices 720B, 720C, respectively, is greater than the length of travel for particles of target material 110F to travel through the protective device 720A. While not required, this extended length of travel for the test pathways 722B and 722C makes it harder for particles of target material 110F that might accidentally or unintentionally still be migrating while in the second mode of operation to reach the vacuum sealing device 105. The test pathway 722C can be a tortuous pathway, one that is marked by repeated twists, bends, or turns as it extends through the bulk of the protective device 720C.

Referring to FIGS. 8A and 8B, another implementation 820 of the protective device 120 is shown in an enlarged sections perspective view. The protective device 820 is annular like the protective device 520. Unlike the protective device 520, the protective device 820 includes a knife-like or triangular protrusion 825 extending out along the Z axis from a central region 826. In some implementations, such as shown in FIG. 8C, the protective device 820C includes a first knife-like or triangular protrusion 825C extending out along the +Z direction from the central region 826 and a second knife-like or triangular protrusion 827C extending out along the −Z direction from the central region 826. The knife-like or triangular protrusions 825 or 825C, 827C can be used for protective devices 820, 820C that are made of more rigid or stiff materials than elastomers. For example, the protective device 820, 820C can be made of a polyimide-based plastic, which can be machined to a high tolerance, is quite durable, and able to withstand temperature cycling between the first mode of operation and the second mode of operation. Because a polyimide-based plastic is stiffer than elastomers, the knife-like or triangular protrusion 825 or protrusions 825C, 827C are added to the bulk central region 826 to improve compression of the protective device 820, 820C between the first fitting 150 and the second fitting 155. The knife-like triangular protrusion 825 or protrusions 825C, 827C weaken the central region 826 such that less force is required to deform the protective device 820, 820C and form the seal between the protective device 820, 820C and the first and second fittings 150, 155. The knife-like triangular protrusions 825 or 825C, 827C are configured to contact the flanges on the first and second fittings 150, 155. This geometry also accommodates manufacturing tolerances of the seal between the protective device 820, 820C and the first and second fittings 150, 155 and the dimensions of the flanges of the first and second fittings 150, 155 because the compression stroke can be adjusted to overcome dimensional tolerances without requiring excessive forces.

These knife-like or triangular protrusions 825 or 825C, 827C are configured to accommodate different flange surfaces at the first and second fittings 150, 155. In other implementations, the protrusions 825, 825C. 827C can have a cross-sectional shape other than a triangle. For example, the protrusions 825, 825C. 827C can have a knife edge, can be a domed shape, or can be a polygonal shape such as a rectangular shape.

Referring to FIG. 9, implementations 900 of the apparatus 100 can be implemented within an extreme ultraviolet (EUV) light source 960. The EUV light source 960 includes a target material generator 961, which prepares target material and supplies or provides a stream of targets 962, which are made from the target material 110S or 110F, to a plasma formation location 963 in an interior 964c of a vacuum chamber 964. The plasma formation location 963 receives at least one light beam 965a, 965b that has been generated by an optical source 966 and delivered to the vacuum chamber 964 by way of an optical path. An interaction between the light beam 965a or 964b and the target material in the target 962 (in the plasma formation location 963) produces a plasma 967 that emits EUV light 968, which is collected by a collector 969 and the collected EUV light 970 is supplied to a lithography exposure apparatus 971. In this example, the target material 110S, 110F can be any material that emits the EUV light 968 when in a plasma state. For example, the target material 110S, 110F can include water, tin, lithium, xenon, and/or any material that, when converted to a plasma state, has an emission line in the EUV range. For example, the target material 110S, 110F can be the element tin, which can be used as pure tin (Sn); as a tin compound, for example, SnBr₄, SnBr₂, SnH₄; as a tin alloy, for example, tin-gallium alloys, tin-indium alloys, tin-indium-gallium alloys, or any combination of these alloys.

The lithography exposure apparatus 971 uses this EUV light 970 to create a pattern on a wafer 972, using any number of process steps, which can be one or more of a combination of process steps such as etching, deposition, and lithography processes with a different mask to create a pattern of openings (such as grooves, channels, or holes) in the material of the wafer 972 or in materials deposited on the wafer 972.

The EUV light source 960 also includes a target material capture apparatus 975 positioned opposite the target material generator 961. The target material capture apparatus 975 is positioned to capture any targets 962 or target material 110S, 110F that is not fully converted to plasma 967.

One or more of the apparatuses 900 can be in fluid communication with the interior 964c such that target material 110S, 110F (such as in the form of targets 962) is able to pass through the apparatus 900. For example, one or more apparatuses 900 can be placed in a fluid flow path of the target material 110S, 110F within the target material generator 961. As another example, one or more apparatuses 900 can be placed in a fluid flow path of the target material 110S, 110F within the target material capture apparatus 975.

The use of the apparatuses 900 within the EUV light source 960 leads to a more reliable EUV light source 960 because there are fewer failures at the vacuum seals between fittings within the EUV light source 960. Accordingly, this leads to a reduction in down time for operating the EUV light source 960.

Referring to FIG. 10, an implementation 1075 of the target material capture apparatus 975 is shown relative to the EUV light source 960. The target material capture apparatus 1075 generally defines a fluid flow passage 1076 through which target material 110S, 110F (for example, from targets 962 not fully converted to plasma 967) can escape the interior 964c. The environment 1011 is defined in the fluid flow passage 1076. The target material capture apparatus 1075 includes a pair of coupling apparatuses 1077 and 1087. The coupling apparatus 1077 is formed from a first fitting 1078 and a second fitting 1079, and the coupling apparatus 1087 is formed from a first fitting 1088 and a second fitting 1089. A first sealing apparatus 1000A is positioned within the coupling apparatus 1077 to seal the first fitting 1078 and the second fitting 1079 and a second sealing apparatus 1000B is positioned within the coupling apparatus 1087 to seal the first fitting 1088 and the second fitting 1089. The first and second sealing apparatuses 1000A, 1000B are generally designed like the apparatus 100. An environment 1011 extends throughout the fluid flow passage 1076, through both coupling apparatuses 1077, 1087. A coupling element 1090, which may be a flexible coupling element, is formed between the second fitting 1079 and the first fitting 1088. The target material capture apparatus 1075 also includes a target material capture device 1072 positioned downstream of the second fitting 1089 to capture the target material 110S, 110F that has flowed through the apparatus 1075. The target material capture device 1072 is able to collect a certain amount of the target material 110S, 110F before it must be disconnected and emptied. To disconnect the device 1072, the second fitting 1089 is disconnected from the first fitting 1088, which breaks the vacuum seal formed in the second sealing apparatus 1000B.

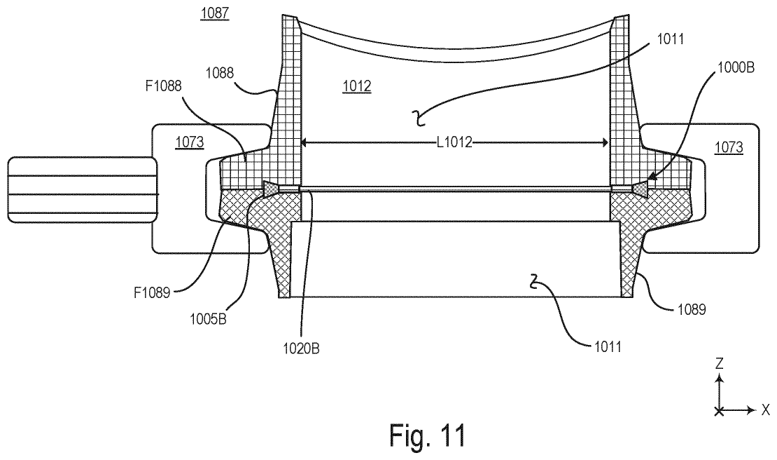

Referring to the close-up view of the coupling apparatus 1087 in FIG. 11, the apparatus 1000B is designed with the principles of the apparatus 100 so that the vacuum sealing device 1005B within the apparatus 1000B is able to maintain the vacuum seal through multiple cycles between the first and second modes of operation because the vacuum sealing device 1005B is protected by the protective device 1020B. Thus, the apparatus 1000B is able to maintain the vacuum seal for a longer period of time, and at least as long as the lifetime of the target material capture device 1072. The first fitting 1088 and the second fitting 1089 are pressed together with force along the Z axis by way of a clamp 1073. The environment 1011 is defined within an open passage 1012 that is defined within the first fitting 1088, the second fitting 1089, and the apparatus 1000B. The open passage 1012 can have an extent or length L1012 taken along the X or Y direction that is about 1 millimeter (mm), greater than 1 mm, greater than 10 mm, greater than 50 mm, or about 60 mm. The clamp 1073 can be a chain clamp that fits over flanges F1088, F1089 protruding from respective first fitting 1088 and second fitting 1089. In other implementations, the clamp 1073 can use a vacuum coupling radiation (VCR) fitting that includes a male nut and a female nut.

Other implementations, such as described below, are within the scope of the claims.

The implementations can be further described using the following clauses.
1. An apparatus comprising:
a vacuum sealing device chemically reactive to a target material in an environment, the vacuum sealing device fixed between a first fitting and a second fitting; and
a protective device chemically non-reactive to the target material, the protective device positioned between the environment and the vacuum sealing device, wherein the protective device defines a test pathway between the environment and the vacuum sealing device when the environment is at a test temperature at which the target material is non-migrating, the test pathway including one or more through pathways within the protective device.
2. The apparatus of clause 1, wherein the vacuum sealing device comprises a soft metal or a polyimide-based plastic.
3. The apparatus of clause 1, wherein the vacuum sealing device comprises a coating over a bulk matter.
4. The apparatus of clause 1, wherein the vacuum sealing device and the protective device each have a closed-path geometry and the protective device is disposed inside the vacuum sealing device.
5. The apparatus of clause 4, wherein the vacuum sealing device and the protective device each have a toroidal geometry and the protective device is disposed radially inside the vacuum sealing device.
6. The apparatus of clause 5, wherein a cross-sectional geometry of the protective device taken along a radial direction includes a rectangular region.
7. The apparatus of clause 5, wherein a cross-sectional geometry of the protective device taken along a radial direction includes at least one a triangular protrusion extending out from a central region.
8. The apparatus of clause 7, wherein the cross-sectional geometry of the protective device taken along a radial direction includes two triangular protrusions, each triangular protrusion extending out from a distinct side of a central region.
9. The apparatus of clause 1, wherein the vacuum sealing device is configured to compress upon joining the first fitting and the second fitting such that a vacuum seal is formed at the vacuum sealing device.

10. The apparatus of clause 1, wherein the protective device comprises a polymer.
11. The apparatus of clause 1, wherein the protective device comprises an elastomer or a polyimide-based plastic.
12. The apparatus of clause 1, wherein the through pathways include through holes that extend through the protective device.
13. The apparatus of clause 12, wherein the through holes comprise conduits that extend through the protective device along an angle that is offset from a radial direction or along a tortuous path through the protective device.
14. The apparatus of clause 1, wherein a cross-sectional area of the test pathway is reduced or eliminated when the environment is at a temperature that is greater than or equal to a melting temperature of the target material.
15. The apparatus of clause 14, wherein the reduced cross-sectional area is small enough to block passage of the target material between the environment and the vacuum sealing device.
16. The apparatus of clause 1, wherein a cross-section of the test pathway between the environment and the vacuum sealing device when the environment is at the test temperature is large enough to permit passage of a test substance from the environment to the vacuum sealing device.
17. The apparatus of clause 16, wherein the test substance comprises helium gas.
18. The apparatus of clause 1, wherein the protective device is non-hermetically sealing.
19. An extreme ultraviolet (EUV) light source comprising:
a chamber defining an interior in which a target material is provided;
at least one sealing apparatus in fluid communication with the interior and configured to seal a first fitting and a second fitting to thereby define an internal environment for target material, the sealing apparatus comprising:
a vacuum sealing device chemically reactive to the target material in the internal environment, the vacuum sealing device fixed between the first and second fittings; and
a protective device chemically non-reactive to the target material, the protective device positioned between the internal environment and the vacuum sealing device, wherein the protective device defines a test pathway between the internal environment and the vacuum sealing device when at a test temperature at which the target material is non-migrating, the test pathway including one or more through pathways within the protective device.
20. The EUV light source of clause 19, wherein the vacuum sealing device comprises a soft metal.
21. The EUV light source of clause 19, wherein the vacuum sealing device and the protective device each have a closed-path geometry and the protective device is disposed radially inside the vacuum sealing device.
22. The EUV light source of clause 21, wherein a cross-sectional geometry of the protective device taken along a radial direction includes at least one a triangular protrusion extending out from a central region.
23. The EUV light source of clause 19, wherein the vacuum sealing device is configured to compress upon joining the first fitting and the second fitting such that a vacuum seal is formed at the vacuum sealing device.
24. The EUV light source of clause 19, wherein the protective device comprises an elastomer or a polyimide-based plastic.
25. The EUV light source of clause 19, wherein the through pathways within the protective device include through holes that extend through the protective device.
26. The EUV light source of clause 25, wherein the through holes extend along a tortuous path through the protective device.

27. The EUV light source of clause 19, wherein the sealing apparatus is positioned in a target material generator or in a target material capture system.
28. The EUV light source of clause 19, wherein the target material comprises tin or a tin alloy.
29. The EUV light source of clause 19, further comprising a clamp adapted to cause the first fitting and the second fitting to become pressed together to form the vacuum seal at the vacuum sealing device between the first fitting and the second fitting.
30. The EUV light source of clause 19, wherein the sealing apparatus is positioned between the chamber interior and a target material capture device.
31. The EUV light source of clause 19, wherein:
a cross-sectional area of the test pathway is reduced when the internal environment is at a temperature that is greater than or equal to a melting temperature of the target material, and the reduced cross-sectional area is small enough to block passage of the target material between the internal environment and the vacuum sealing device; and
a cross-section of the test pathway between the internal environment and the vacuum sealing device when the internal environment is at a test temperature below the melting temperature of the target material is large enough to permit passage of a test substance from the environment to the vacuum sealing device.
32. An apparatus comprising:
a vacuum sealing device chemically reactive to a target material in an environment, the vacuum sealing device fixed between a first fitting and a second fitting; and
a protective device chemically non-reactive to the target material, the protective device positioned between the environment and the vacuum sealing device,
wherein, when the apparatus is in a first mode of operation, the protective device defines one or more test pathways between the environment and the vacuum sealing device, the one or more test pathways including one or more through pathways within the protective device, and when the apparatus is in a second mode of operation, the protective device blocks passage of target material from the environment to the vacuum sealing device.
33. The apparatus of clause 32, wherein, in the second mode of operation, the one or more test pathways have a reduced cross-sectional area that is small enough to block passage of the target material from the environment to the vacuum sealing device.
34. A method comprising:
operating an apparatus in a first mode of operation in which a protective device adjacent an environment defines one or more test pathways between the environment and a vacuum sealing device and through the protective device, the vacuum sealing device positioned between a first fitting and a second fitting that define the environment; and
operating the apparatus in a second mode of operation in which the protective device blocks passage of target material from the environment to the vacuum sealing device.

The above-described implementations and other implementations are within the scope of the following claims.

1. An apparatus comprising:
a vacuum sealing device chemically reactive to a target material in an environment, the vacuum sealing device fixed between a first fitting and a second fitting; and
a protective device chemically non-reactive to the target material, the protective device positioned between the environment and the vacuum sealing device, wherein the protective device defines a test pathway between the environment and the vacuum sealing device when the environment is at a test temperature at which the target material is non-migrating, the test pathway including one or more through pathways within the protective device.

2. The apparatus of claim 1, wherein the vacuum sealing device comprises a soft metal or a polyimide-based plastic.

3. The apparatus of claim 1, wherein the vacuum sealing device and the protective device each have a closed-path geometry and the protective device is disposed inside the vacuum sealing device closer to the environment.

4. The apparatus of claim 1, wherein a cross-sectional geometry of the protective device taken along a radial direction includes at least one of a rectangular region and at least one triangular protrusion extending out from a central region.

5. The apparatus of claim 1, wherein the protective device comprises an elastomer or a polyimide-based plastic.

6. The apparatus of claim 1, wherein the through pathways include through holes that extend through the protective device.

7. The apparatus of claim 6, wherein the through holes comprise conduits that extend through the protective device along an angle that is offset from a radial direction or along a tortuous path through the protective device.

8. The apparatus of claim 1, wherein a cross-sectional area of the test pathway is reduced or eliminated when the environment is at a temperature that is greater than or equal to a melting temperature of the target material.

9. The apparatus of claim 8, wherein the reduced cross-sectional area is small enough to block passage of the target material between the environment and the vacuum sealing device.

10. The apparatus of claim 1, wherein a cross-section of the test pathway between the environment and the vacuum sealing device when the environment is at the test temperature is large enough to permit passage of a test substance from the environment to the vacuum sealing device.

11. The apparatus of claim 10, wherein the test substance comprises helium gas.

12. An extreme ultraviolet (EUV) light source comprising:
a chamber defining an interior in which a target material is provided;
at least one sealing apparatus in fluid communication with the interior and configured to seal a first fitting and a second fitting to thereby define an internal environment for target material, the sealing apparatus comprising:
a vacuum sealing device chemically reactive to the target material in the internal environment, the vacuum sealing device fixed between the first and second fittings; and
a protective device chemically non-reactive to the target material, the protective device positioned between the internal environment and the vacuum sealing device, wherein the protective device defines a test pathway between the internal environment and the vacuum sealing device when at a test temperature at which the target material is non-migrating, the test pathway including one or more through pathways within the protective device.

13. The EUV light source of claim 12, wherein the vacuum sealing device comprises a soft metal.

14. The EUV light source of claim 12, wherein the vacuum sealing device and the protective device each have a closed-path geometry and the protective device is disposed radially inside the vacuum sealing device.

15. The EUV light source of claim 14, wherein a cross-sectional geometry of the protective device taken along a radial direction includes at least one a triangular protrusion extending out from a central region.

16. The EUV light source of claim 12, wherein the protective device comprises an elastomer or a polyimide-based plastic.

17. The EUV light source of claim 12, wherein the through pathways within the protective device include through holes that extend through the protective device along a tortuous path.

18. The EUV light source of claim 12, wherein the sealing apparatus is positioned in a target material generator or in a target material capture system.

19. The EUV light source of claim 12, further comprising a clamp adapted to cause the first fitting and the second fitting to become pressed together to form the vacuum seal at the vacuum sealing device between the first fitting and the second fitting.

20. The EUV light source of claim 12, wherein the sealing apparatus is positioned between the chamber interior and a target material capture device.

21. The EUV light source of claim 12, wherein:
a cross-sectional area of the test pathway is reduced when the internal environment is at a temperature that is greater than or equal to a melting temperature of the target material, and the reduced cross-sectional area is small enough to block passage of the target material between the internal environment and the vacuum sealing device; and
a cross-section of the test pathway between the internal environment and the vacuum sealing device when the internal environment is at a test temperature below the melting temperature of the target material is large enough to permit passage of a test substance from the environment to the vacuum sealing device.

22. A method comprising:
operating an apparatus in a first mode of operation in which a protective device adjacent an environment defines one or more test pathways between the environment and a vacuum sealing device and through the protective device, the vacuum sealing device positioned between a first fitting and a second fitting that define the environment; and
operating the apparatus in a second mode of operation in which the protective device blocks passage of target material from the environment to the vacuum sealing device.
